(19) United States
(12) Patent Application Publication
(10) Pub. No.: US 2024/0357909 A1
(43) Pub. Date: Oct. 24, 2024

(54) LIGHT EMITTING APPARATUS, DISPLAY APPARATUS, IMAGING APPARATUS, AND ELECTRONIC DEVICE

(71) Applicant: CANON KABUSHIKI KAISHA, Tokyo (JP)

(72) Inventors: HIROAKI SANO, Tokyo (JP); SHOMA HINATA, Kanagawa (JP); YOJIRO MATSUDA, Kanagawa (JP)

(21) Appl. No.: 18/760,833

(22) Filed: Jul. 1, 2024

Related U.S. Application Data
(63) Continuation of application No. PCT/JP2022/000066, filed on Jan. 5, 2022.

(51) Int. Cl. H10K 59/80; H04M 1/02; H04N 23/63; H10K 59/122; H10K 59/35

(52) U.S. Cl. CPC H10K 59/879; H10K 59/122; H10K 59/351; H10K 59/352; H04M 1/0266; H04N 23/63

(57) ABSTRACT

A light emitting apparatus includes a substrate including a principal surface, first to fourth light emitting elements configured to emit first light or second light, first to fourth lenses, wherein relationships between sizes of light emitting regions and relative positions of lenses differ between the first light and the second light.

### CROSS-REFERENCE TO RELATED APPLICATIONS

This application is a Continuation of International Patent Application No. PCT/JP2022/000066, filed Jan. 5, 2022, which is hereby incorporated by reference herein in its entirety.

### BACKGROUND OF THE INVENTION

### Field of the Invention

The present invention relates to a light emitting apparatus, a display apparatus, an imaging apparatus, and an electronic device that include an optical member such as a microlens.

### Background Art

An organic light emitting element is an element including a first electrode and a second electrode, and an organic compound layer arranged therebetween, and is a light emitting device that emits light when carriers are injected from the first electrode and the second electrode. Because the organic light emitting element is a device that is light in weight and can be made flexible, a display apparatus including the organic light emitting element has recently attracted attention. For higher resolution of the display apparatus, a method using an organic light emitting element that emitting white light, and a color filter (CF) (hereinafter, will be referred to as a white+CF method) has been known. Because the white+CF method forms an organic layer over the entire surface of a substrate, as compared with a method of forming an organic layer for each color using a metal mask, it is relatively easy to enhance resolution by controlling a pixel size and a pitch between pixels.

Patent Literature 1 discusses using a display apparatus including an organic light emitting element together with an optical system.

FIG. 14 is a diagram schematically illustrating a light ray traveling from an organic light emitting apparatus to an eyeball of a user in a case where the organic light emitting apparatus is used together with an optical system. In a case where an organic light emitting apparatus 110 is used together with an optical lens 120 as illustrated in FIG. 14, in a center region located at the central portion of a display region, a light ray traveling toward a front direction with respect to a display surface is used. In contrast to this, in an outer circumferential region located at an outer circumferential portion of the display region, a light ray traveling in an oblique direction with respect to the display surface is used, and an image is formed on an eyeball 130.

In other words, in an organic light emitting element located in the outer circumferential region, because light that is emitted at a wide angle from an organic light emitting element is used, it is demanded to improve viewing angle characteristics of the organic light emitting element. Patent Literature 1 discusses a display apparatus with viewing angle characteristics improved by arranging the center of a light emitting surface of a light output unit and the center of a color filter so as to be shifted relative to each other.

Patent Literature 2 discusses a display apparatus including an output coupling component that reduces the total reflection and extracts light with a wide viewing angle.

### CITATION LIST

### Patent Literature

Patent Literature 1: International Publication WO2017/169563
Patent Literature 2: Japanese Patent Application Laid-Open No. 2017-017013

The display apparatuses discussed in Patent Literatures 1 and 2 can use light having a wide viewing angle for display.

Nevertheless, of light emitted by an organic light emitting element that emits light having a wide viewing angle, the ratio of light contributing to display is small, and the countermeasure for chromaticity shift varies depending on the wavelength of extracted light. Thus, there has been a room for improvement in the position of a lens and the size of a light emitting region.

### SUMMARY OF THE INVENTION

The present invention has been devised in view of the above-described problem, and is directed to providing a light emitting apparatus in which, in a case where a lens is used, reduction of a color shift attributed to a viewing angle is adjusted for each color.

According to an aspect of the present invenion, a light emitting apparatus includes a substrate including a principal surface, a first light emitting element, a second light emitting element, a third light emitting element, and a fourth light emitting element that are arranged on the principal surface, a first lens that light emitted by the first light emitting element enters, a second lens that light emitted by the second light emitting element enters, a third lens that light emitted by the third light emitting element enters, a fourth lens that light emitted by the fourth light emitting element enters, a first insulating layer defining a light emitting region of the first light emitting element, a second insulating layer defining a light emitting region of the second light emitting element, a third insulating layer defining a light emitting region of the third light emitting element, and a fourth insulating layer defining a light emitting region of the fourth light emitting element, wherein the first light emitting element and the second light emitting element emit first light that is fluorescent light, and the third light emitting element and the fourth light emitting element emit second light in a wavelength different from that of the first light and is phosphorescent light, wherein, in a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface, wherein a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface, wherein a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface, wherein a size of the light emitting region of the second light emitting element is equal to or smaller than a size of the light emitting region of the first light emitting element, wherein a size of the light emitting region of the fourth light emitting element is smaller than a size of the light emitting region of the third light emitting element, and wherein a difference between the size of the light emitting region of the second light emitting element and the size of the light emitting region of the first light emitting element is equal to or smaller than a difference between the size of the light emitting region of the fourth light emitting element and the size of the light emitting region of the third light emitting element.

Further features of the present invention will become apparent from the following description of exemplary embodiments with reference to the attached drawings.

### BRIEF DESCRIPTION OF THE DRAWINGS

FIG. 1A is a cross-sectional view illustrating a first light emitting element included in a light emitting apparatus according to an exemplary embodiment of the present invention.

FIG. 1B is a plan view illustrating the first light emitting element in FIG. 1A.

FIG. 1C is a plan view illustrating the first light emitting element in FIG. 1A.

FIG. 2A is a cross-sectional view illustrating a second light emitting element included in a light emitting apparatus according to an exemplary embodiment of the present invention.

FIG. 2B is a plan view illustrating the second light emitting element in FIG. 2A.

FIG. 2C is a plan view illustrating the second light emitting element in FIG. 2A.

FIG. 3 is a schematic cross-sectional view illustrating a light emitting apparatus according to a comparative example.

FIG. 4A is a plan view of a light emitting apparatus according to an exemplary embodiment of the present invention.

FIG. 4B is a cross-sectional view taken along a line A-A′ in FIG. 4A.

FIG. 5A is a graph indicating a panel position and a degree of color shift of a light emitting apparatus according to an exemplary embodiment of the present invention.

FIG. 5B is a graph indicating a panel position and a degree of color shift of a light emitting apparatus according to a comparative example.

FIG. 6 is a schematic cross-sectional view illustrating a light emitting apparatus according to an exemplary embodiment of the present invention.

FIG. 7 is a schematic cross-sectional view illustrating a lens according to an exemplary embodiment of the present invention.

FIG. 8A is a schematic cross-sectional view illustrating a pixel of a light emitting apparatus according to an exemplary embodiment of the present invention.

FIG. 8B is a schematic cross-sectional view illustrating a light emitting apparatus according to an exemplary embodiment of the present invention.

FIG. 9 is a schematic diagram illustrating a display apparatus according to an exemplary embodiment of the present invention.

FIG. 10A is a schematic diagram illustrating an imaging apparatus according to an exemplary embodiment of the present invention.

FIG. 10B is a schematic diagram illustrating an electronic device according to an exemplary embodiment of the present invention.

FIG. 11A is a schematic diagram illustrating a light emitting apparatus according to an exemplary embodiment of the present invention.

FIG. 11B is a schematic diagram illustrating a foldable display apparatus.

FIG. 12A is a schematic diagram illustrating an illumination apparatus according to an exemplary embodiment of the present invention.

FIG. 12B is a schematic diagram of a movable body according to an exemplary embodiment of the present invention.

FIG. 13A is a schematic diagram illustrating a wearable device according to an exemplary embodiment of the present invention.

FIG. 13B is a schematic diagram illustrating a configuration in which a wearable device includes an imaging apparatus according to an exemplary embodiment of the present invention.

FIG. 14 is a schematic diagram illustrating a positional relationship between a lens, a light emitting apparatus, and an observer.

### DESCRIPTION OF THE EMBODIMENTS

A light emitting apparatus according to an exemplary embodiment of the present invention includes a substrate having a principal surface, a first light emitting element, a second light emitting element, a third light emitting element, and a fourth light emitting element that are arranged on the principal surface, a first lens that light emitted by the first light emitting element enters, a second lens that light emitted by the second light emitting element enters, a third lens that light emitted by the third light emitting element enters, a fourth lens that light emitted by the fourth light emitting element enters, a first insulating layer that defines a light emitting region of the first light emitting element, a second insulating layer that defines a light emitting region of the second light emitting element, a third insulating layer that defines a light emitting region of the third light emitting element, and a fourth insulating layer that defines a light emitting region of the fourth light emitting element, in which the first light emitting element and the second light emitting element emit first light that is fluorescent light, and the third light emitting element and the fourth light emitting element emit second light that has a wavelength different from that of the first light and is phosphorescent light. In a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface, a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface, a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface, a size of the light emitting region of the second light emitting element is equal to or smaller than a size of the light emitting region of the first light emitting element, a size of the light emitting region of the fourth light emitting element is smaller than a size of the light emitting region of the third light emitting element, and a difference between the size of the light emitting region of the second light emitting element and the size of the light emitting region of the first light emitting element is equal to or smaller than a difference between the size of the light emitting region of the fourth light emitting element and the size of the light emitting region of the third light emitting element.

The light emitting region of the second light emitting element may be smaller than the light emitting region of the first light emitting element, and the light emitting region of the fourth light emitting element may be smaller than the light emitting region of the third light emitting element. In addition, the light emitting region of the fourth light emitting element may be smaller than the light emitting region of the second light emitting element.

The second light emitting element and the fourth light emitting element may be light emitting elements configured to emit light at a wide angle toward the display apparatus. In the second light emitting element and the fourth light emitting element, in order to emit light at a wide angle, a lens is arranged so as to be shifted as compared to the first light emitting element.

In this case, the contribution of the second light emitting element and the fourth light emitting element to light emission of the display apparatus is proportionally smaller than that of the first light emitting element and the third light emitting element. This is because light emission from the first light emitting element and the third light emitting element entirely contributes to the light emission of the display apparatus, whereas light emission from the second light emitting element and the fourth light emitting element only partially contributes to the light emission of the display apparatus.

To reduce power for emitted light that does not contribute to light emission in the second light emitting element, the light emitting regions of the second light emitting element and the fourth light emitting element are smaller than those of the first light emitting element and the third light emitting element. Because the light emitting regions are small, light emission amounts of the light emitting elements become smaller, but the rate of contribution to the light emission of the display apparatus increase. Consequently, power consumption of the display apparatus is reduced. In a case where the light emitting region of the fourth light emitting element is smaller than the light emitting region of the third light emitting element, the light emitting region of the first light emitting element and the light emitting region of the second light emitting element may have the same size. This is because power consumption is reduced since the light emitting region of the fourth light emitting element is made smaller than the light emitting region of the third light emitting element.

The first light emitting element and the second light emitting element emit first light that is fluorescence. The third light emitting element and the fourth light emitting element emit second light in a wavelength different from that of the first light. The second light is phosphorescence. Because the wavelengths are different, a difference in size of light emitting region between the first and the second light emitting elements differs from a difference in size of light emitting region between the third and the fourth light emitting elements. The wavelength of the first light may be shorter than the wavelength of the second light, and the first light may be blue light, and the second light may be green light.

As compared with an amount of light that is emitted by the first light emitting element and enters the first lens, an amount of light that is emitted by the second light emitting element and enters the second lens may be smaller. It can also be said that the lens efficiency of the second lens is smaller than the lens efficiency of the first lens. The lens efficiency of the first lens is a ratio of an amount of light that has entered the first lens to an amount of light emitted by the first light emitting region. The lens efficiency can be adjusted by changing relative positions of a light emitting region and a lens. In a case where positions of lenses are determined, the position of a light emitting region with high lens efficiency is determined. The position at which lens efficiency is high can be called a sweet spot.

In this specification, a lens may be provided on a light extraction side of a light emitting apparatus, and the lens may be convex towards the light extraction side. In a case where the light emitting apparatus emits light from both of a lower electrode side and an upper electrode side of a light emitting element, both directions can be called the light extraction side.

In this specification, a lens may be an optical member including a so-called microlens. A lens shape may be whichever of a spherical shape and an aspherical shape. Furthermore, the lens may be a gradient index lens of which a refractive index changes from the center of the lens toward the outside in a radius direction, or a so-called digital microlens in which ring-shaped patterns of a high refractive index material and a low refractive index material are roughly arranged.

Hereinafter, exemplary embodiments will be described with reference to the drawings. The following exemplary embodiments are not intended to limit the present invention. A plurality of configurations is described in the exemplary embodiments, but not all of the plurality of configurations are always essential to the present invention. In addition, the plurality of configurations may be arbitrarily combined. In the drawings, the same or similar components are assigned the same reference numerals, and the redundant description thereof may be omitted.

### First Exemplary Embodiment

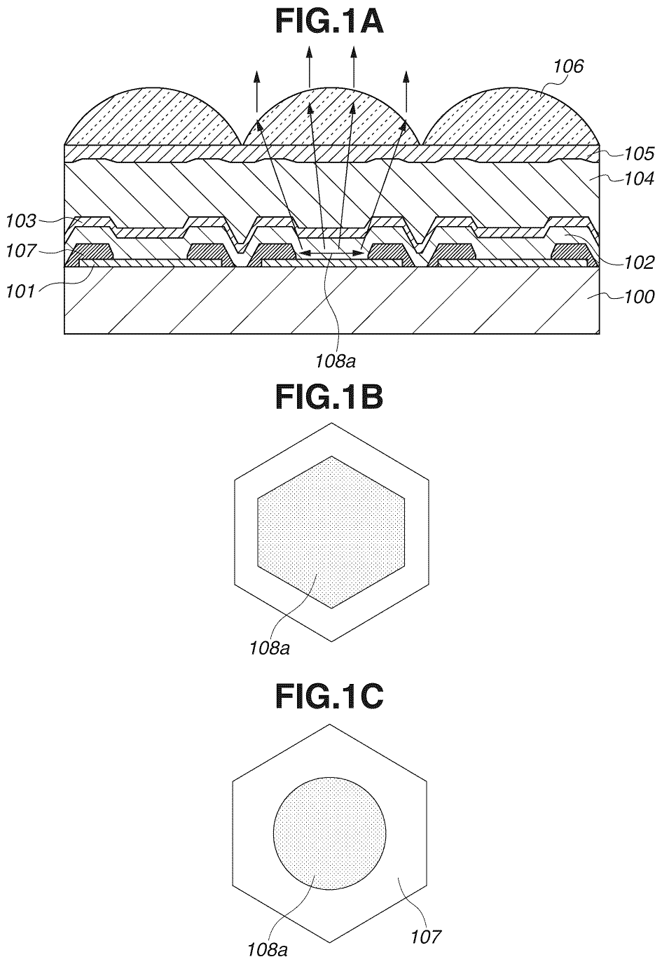

FIGS. 1A to 1C are diagrams illustrating an example of a first light emitting element and a third light emitting element of a light emitting apparatus according to a first exemplary embodiment of the present invention. FIG. 1A is a cross-sectional view of the first light emitting element and the third light emitting element, and FIG. 1B is a plan view of the first light emitting element and the third light emitting element in FIG. 1A. In the present exemplary embodiment, because the plan view of the first light emitting element and the plan view of the third light emitting element are the same except that the first light emitting element emits light with a first color, and the third light emitting element emits light with a second color different from the first color, the first light emitting element and the third light emitting element are illustrated using one plan view.

The light emitting apparatus in FIG. 1A includes a lower electrode 101, a function layer 102 including a light emitting layer, an upper electrode 103, a protective layer 104, a planarization layer 105, a microlens 106, and an insulating layer 107 covering both ends of the lower electrode 101, which are provided above a substrate 100. The insulating layer 107 is also called a pixel isolation film or a bank. In a case where the planarization layer 105 is made of resin, the planarization layer 105 may be called a resin layer. The cross-sectional view in FIG. 1A illustrates a cross section vertical to the principal surface of the substrate 100. The plan view in FIG. 1B is a plan view observed from a direction vertical to the principal surface of the substrate 100.

The ends of the lower electrode 101 are in contact with and covered by the insulating layer 107. A portion of the lower electrode 101 that is not in contact with the insulating layer 107 may be in contact with the function layer 102. A region in which the lower electrode 101 and the function layer 102 are in contact with each other is a light emitting region 108a that emits light when an electrical field is applied between the lower electrode 101 and the upper electrode 103.

The light emission from the light emitting region 108a at the time of application of the electrical field may be determined by observation from the same direction as FIG. 1B. The light emitting region 108a may be determined by measurement of a distance from the end of a first insulating layer covering the left side end of the lower electrode 101 to the end of a second insulating layer covering the right side end of the lower electrode 101 in FIGS. 1A to 1C. The end of the insulating layer 107 may be a contact point between the lower electrode 101 and the insulating layer 107.

In FIG. 1B, the light emitting region 108a is surrounded by the insulating layer 107. In the present exemplary embodiment, the light emitting region 108a is a hexagon, but may have another shape. For example, FIG. 1C illustrates an example in which the light emitting region 108a has a circular shape. Aside from these, the shape of the light emitting region 108a may be an elliptical shape, or stripe arrangement in which rectangular red, green and blue (RGB) light emitting regions are arranged and light is emitted therefrom may be adopted.

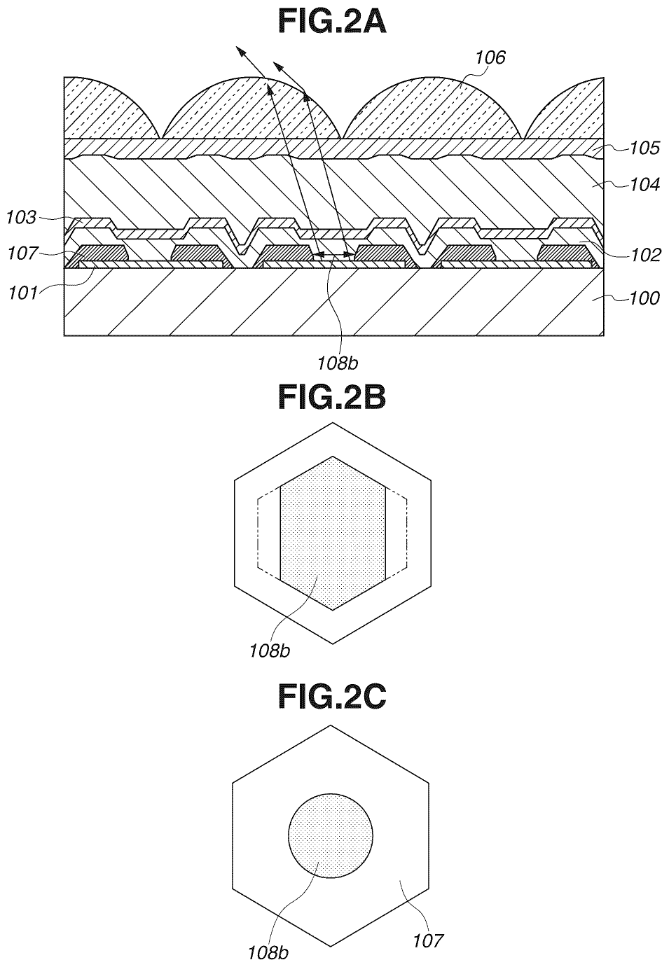

FIGS. 2A to 2C are diagrams illustrating a second light emitting element of the light emitting apparatus according to an exemplary embodiment of the present invention, and the second light emitting element emits light with the first color. FIG. 2A is a cross-sectional view of the second light emitting element, and FIG. 2B is a plan view of the second light emitting element in FIG. 2A. The cross-sectional view and the plan views are similar to those in FIGS. 1A to 1C. FIG. 2C illustrates an example in which a light emitting region 108b has a circular shape. A fourth light emitting element also has a similar configuration.

The second light emitting element has a configuration similar to that of the first light emitting element. In a direction parallel to the principal surface of the substrate 100, a distance between a midpoint of the light emitting region 108b and a vertex of the microlens 106 in the second light emitting element is larger than a distance between a midpoint of the light emitting region 108a and a vertex of the microlens 106 in the first light emitting element. It can also be said that, if the position of the microlens 106 in the first light emitting element is assumed as a normal position, the position of the microlens 106 in the second light emitting element is shifted.

In a case where the microlens 106 is a convex lens, on a plane vertical to the principal surface of the substrate 100, the vertex of the microlens 106 is at the farthest position from the principal surface. In a case where the microlens 106 is a concave lens, on the plane vertical to the principal surface of the substrate 100, the vertex of the microlens 106 is at the closest position from the principal surface. The vertex of the microlens 106 can also be regarded as the center of the microlens 106 in a cross section parallel to the principal surface of the substrate 100.

The light emitting region 108b of the second light emitting element is smaller than the light emitting region 108a of the first light emitting element. In other words, the light emitting region 108b in FIG. 2A is shorter as a line segment than the light emitting region 108a in FIG. 1A. This can also be said that an area in which the function layer 102 is in contact with the lower electrode 101 is small.

By making the light emitting region 108a of the second light emitting element small in this manner, power consumption is reduced.

On the other hand, FIG. 2B illustrates a configuration of the light emitting region 108b. In the present exemplary embodiment, two sides of the light emitting region 108b on the right and left sides of the drawing paper are arranged on the inner side of the hexagon of the light emitting region 108a. In other words, the light emitting region 108b of the second light emitting element is a hexagon, and at least one side of the hexagon is arranged on the inner side of the hexagon as compared to the light emitting region 108a of the first light emitting element. In addition, sides of the hexagon are a pair of sides farthest from each other among sides of the hexagon.

In the present exemplary embodiment, two sides of the hexagon are arranged on the inner side of the hexagon as compared to the light emitting region 108a, but it is sufficient that at least one side of the polygon is arranged on the inner side of the polygon as compared to the light emitting region 108a of the first light emitting element.

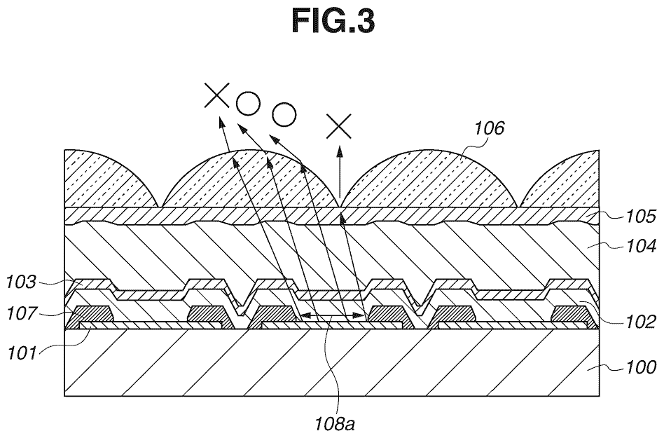

FIG. 3 is a cross-sectional view illustrating a comparative example. In this configuration, a positional relationship between the light emitting region of the second light emitting element and the optical member differs from a positional relationship between the light emitting region of the first light emitting element and the optical member, but the light emitting region of the second light emitting element has the same size as the light emitting region of the first light emitting element. The state in which the positional relationship of the light emitting region and the optical member in the second light emitting element is different from that in the first light emitting element may be said to be a state in which the optical member is shifted. A direction in which the optical member is shifted may be a direction in which light emitted from the light emitting layer is desired to be refracted.

As illustrated in FIG. 3, light from the end of the light emitting region 108a is less likely to be refracted in the oblique direction. On the other hand, light from the central portion of the light emitting region 108a can be easily refracted in the oblique direction.

Light rays traveling toward the left side in FIG. 3, i.e., light rays indicated by the symbol “∘” in FIG. 3, correspond to light contributing to the light emission of a display apparatus. When the left side in FIG. 3 is assumed as an outer peripheral side of a display region, in an outer peripheral region located in an outer peripheral portion of the display region, light traveling in the oblique direction with respect to a display surface is used. Other light rays, i.e., light rays indicated by the symbol “x” in FIG. 3, correspond to light that does not contribute to the light emission of the display apparatus. Thus, by emitting light only from a region in which light can be refracted in the oblique direction, as in the configuration described in the first exemplary embodiment with reference to FIGS. 1A to 1C and 2A to 2C, it is possible to improve light use efficiency and provide a light emitting apparatus with low power consumption.

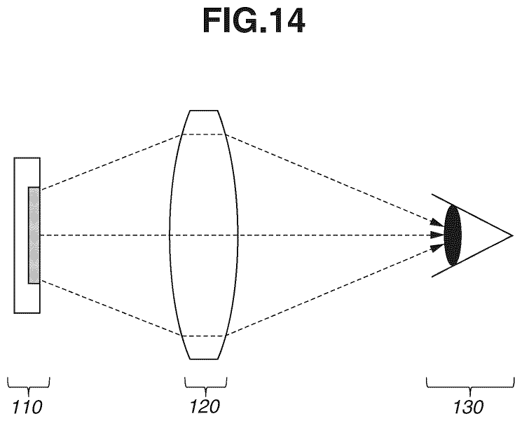

In many cases, a display apparatus that uses light traveling in the oblique direction with respect to the display surface is a display apparatus that includes a display unit and an optical system in an outer peripheral region of the display apparatus and in which a user views the display unit via the optical system. In the configuration of such a display apparatus, preventing emission of unused light brings about the following additional effect. For example, if light not to be used enters the optical lens 120 in FIG. 14, the light becomes stray light and might deteriorate the quality of display. Because light not contributing to display is prevented from being emitted in the above-described exemplary embodiment, an effect of reducing stray light is also produced. In addition, because this effect differs between first light and second light, a change in size of light emitting region differs between the light emitting element that emits the first light and the light emitting element that emits the second light.

In this manner, a light emitting region with small contribution to the light emission of a display apparatus can be made small like the light emitting region of the second light emitting element.

According to the present exemplary embodiment, because the light emission of the second light emitting element and the light emission of the fourth light emitting element efficiently contribute to the light emission of the display apparatus, power consumption can be reduced.

In the present exemplary embodiment, the light emitting region of the fourth light emitting element is made smaller than the light emitting region of the second light emitting element in such a manner that a difference between the viewing angle dependency of the luminance of a first color and the viewing angle dependency of the luminance of a second color different from the first color is smaller.

In this manner, a difference between the intensity of light emitted toward the direction facing the front of the display apparatus from the third light emitting element, and the intensity of light emitted in a wide-angle direction of the display apparatus from the fourth light emitting element, and a difference between the intensity of light emitted toward the direction facing the front of the display apparatus from the first light emitting element, and the intensity of light emitted in the wide-angle direction of the display apparatus from the second light emitting element is small. In other words, it is possible to provide a light emitting apparatus in which power consumption and a color shift attributed to a viewing angle are reduced.

### Second Exemplary Embodiment

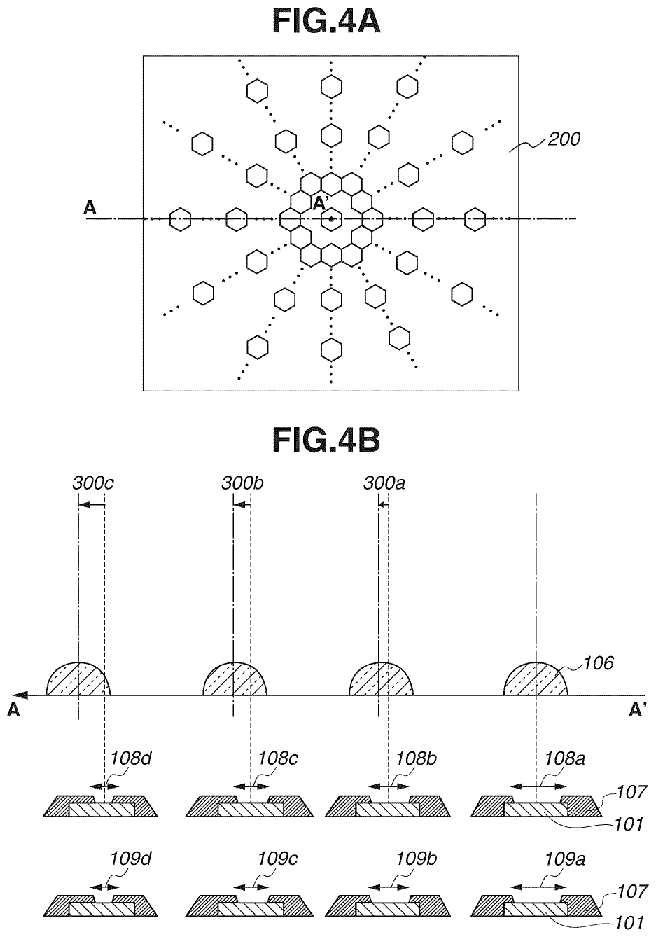

FIGS. 4A and 4B are diagrams illustrating an example of a light emitting apparatus according to a second exemplary embodiment of the present invention. FIG. 4A is a diagram illustrating the light emitting apparatus as viewed in the plan view from the direction vertical to the principal surface of the substrate, similarly to FIG. 1B. A display region 200 includes a plurality of light emitting elements. Using a central portion A′ and an outer peripheral portion A, a positional relationship between a light emitting region and a microlens will be described.

FIG. 4B is a cross-sectional view illustrating a part of a cross section taken along a straight line passing through A-A′ in FIG. 4A. In the cross section, a part of light emitting elements is omitted. A positional relationship between the microlens 106, a light emitting region 108 that emits light with the first color, and a light emitting region 109 that emits light with the second color changes from the central portion A′ toward the outer peripheral portion A. Specifically, assuming that a positional relationship between the light emitting region 108a and the microlens 106 immediately above the light emitting region 108a is a reference, in a positional relationship between the light emitting region 108b and a microlens immediately above the light emitting region 108b, the microlens is relatively shifted in the left direction in FIG. 4B by an amount equal to a microlens shift amount 300a. In addition, the light emitting region 108b is smaller than the light emitting region 108a. In a similar manner, a light emitting region 108c is smaller than the light emitting region 108b, and a microlens immediately above the light emitting region 108c is relatively shifted by an amount equal to a microlens shift amount 300b. Furthermore, a light emitting region 108d is smaller than the light emitting region 108c, and a microlens immediately above the light emitting region 108d is relatively shifted by an amount equal to a microlens shift amount 300c. In a similar manner, light emitting elements including light emitting regions 109a to 109d are illustrated in descending order of size.

A light emitting element arranged between the light emitting regions 108a and 108b may have the same size as the light emitting region 108a, may have the same size as the light emitting region 108b, may be smaller than the light emitting region 108a, or may be larger than the light emitting region 108b. A plurality of light emitting elements arranged between the light emitting regions 108a and 108b may include respective light emitting regions that become larger as getting closer to the light emitting region 108a, or become smaller as getting closer to the light emitting region 108b. The same applies to the light emitting regions 109 of the third light emitting element and the fourth light emitting element that emit light with the second color.

A configuration may be adopted in which the shift of the microlens may become larger continuously or may become larger in a phased manner as getting closer to the outer peripheral portion A from the central portion A′ of the display region. In this manner, by arranging the light emitting regions such that the sizes of the light emitting regions are smaller continuously or in a phased manner, it is possible to reduce light not contributing to the light emission of the display apparatus in the display region. Furthermore, by making the light emitting regions 109 of the light emitting elements that emit light with the second color smaller in size than the light emitting regions 108 of the light emitting elements that emit light with the first color, it is possible to reduce a variation in viewing angle characteristics of luminance among colors.

Among the light emitting elements, a light emitting element closer to the outer peripheral portion A than to the central portion A′ in FIG. 4A, for example, is an external light emitting element. It can also be said that a light emitting element farther from the central portion A′ is an external light emitting element.

In other words, the light emitting apparatus according to the present exemplary embodiment may adopt a configuration in which a shift between a microlens and a light emitting region continuously becomes larger. Specifically, the light emitting apparatus according to the present exemplary embodiment includes a substrate having a principal surface, first, second, third, and fourth light emitting elements, a first lens that light emitted by the first light emitting element enters, a second lens that light emitted by the second light emitting element enters, a third lens that light emitted by the third light emitting element enters, and a fourth lens that light emitted by the fourth light emitting element enters. In the light emitting apparatus according to the present exemplary embodiment, in a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface, and a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface. On the other hand, a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface. Furthermore, the light emitting region of the second light emitting element is smaller than the light emitting region of the first light emitting element, and the light emitting region of the fourth light emitting element is smaller than the light emitting region of the third light emitting element, and the light emitting region of the fourth light emitting element is smaller than the light emitting region of the second light emitting element. The first and the second light emitting elements emit first light, and the third and fourth light emitting elements emit second light in a wavelength different from that of the first light. It can be said that the second light has a color different from that of the first light.

In addition, a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface may be equal to a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface.

The light emitting element arranged between the light emitting regions 108a and 108b in the present exemplary embodiment can also be represented as a fifth light emitting element. In other words, the light emitting apparatus according to the present exemplary embodiment further includes a fifth light emitting element that is arranged between the first light emitting element and the second light emitting element and adjacent to the second light emitting element, and a fifth lens that light emitted by the fifth light emitting element enters. It can be said that, in the light emitting apparatus according to the present exemplary embodiment, in the cross section vertical to the principal surface, a distance between a midpoint of a light emitting region of the fifth light emitting element and a vertex of the fifth lens in the direction parallel to the principal surface is equal to the distance between the midpoint of the light emitting region of the second light emitting element and the vertex of the second lens in the direction parallel to the principal surface.

In this case, a difference between a size of the light emitting region of the fifth light emitting element and a size of the light emitting region of the second light emitting element may be smaller than a difference between the size of the light emitting region of the second light emitting element and a size of the light emitting region of the first light emitting element. More specifically, the size of the light emitting region of the fifth light emitting element may be the same as the size of the light emitting region of the second light emitting element.

A light emitting element arranged at a position closer to the outside of the substrate than the light emitting region 108b, specifically, a light emitting element arranged between the light emitting regions 108b and 108c, can be called a sixth light emitting element. In other words, the light emitting apparatus according to the present exemplary embodiment includes a sixth light emitting element adjacent to the second light emitting element, and a sixth lens that light emitted by the sixth light emitting element enters, and the second light emitting element is arranged between the first light emitting element and the sixth light emitting element. In the cross section vertical to the principal surface, a distance between a midpoint of a light emitting region of the sixth light emitting element and a vertex of the sixth lens in the direction parallel to the principal surface may be larger than the distance between the midpoint of the light emitting region of the second light emitting element and the vertex of the second lens in the direction parallel to the principal surface.

In this case, the light emitting region of the sixth light emitting element may be smaller in size than the light emitting region of the second light emitting element.

As in the above-described relationship in the light emitting elements that emits light with the first light, also in light emitting elements that emits light with the second light, a seventh light emitting element and an eighth light emitting element can be provided. In other words, the light emitting apparatus according to the present exemplary embodiment may include the seventh light emitting element that is arranged between the third light emitting element and the fourth light emitting element and adjacent to the fourth light emitting element, and a seventh lens that light emitted by the seventh light emitting element enters. In the light emitting apparatus according to the present exemplary embodiment, in the cross section vertical to the principal surface, a distance between a midpoint of a light emitting region of the seventh light emitting element and a vertex of the seventh lens in the direction parallel to the principal surface may be equal to the distance between the midpoint of the light emitting region of the fourth light emitting element and the vertex of the fourth lens in the direction parallel to the principal surface.

In this case, a difference between a size of the light emitting region of the seventh light emitting element and a size of the light emitting region of the fourth light emitting element may be smaller than a difference between the size of the light emitting region of the fourth light emitting element and a size of the light emitting region of the third light emitting element.

On the other hand, the light emitting apparatus according to the present exemplary embodiment includes the eighth light emitting element adjacent to the fourth light emitting element, and an eighth lens that light emitted by the eighth light emitting element enters, and the fourth light emitting element is arranged between the third light emitting element and the eighth light emitting element. In the light emitting apparatus according to the present exemplary embodiment, in the cross section vertical to the principal surface, a distance between a midpoint of a light emitting region of the eighth light emitting element and a vertex of the eighth lens in the direction parallel to the principal surface may be larger than the distance between the midpoint of the light emitting region of the fourth light emitting element and the vertex of the fourth lens in the direction parallel to the principal surface.

In this case, the light emitting region of the eighth light emitting element may be smaller in size than the light emitting region of the fourth light emitting element.

On the other hand, the light emitting apparatus according to the present exemplary embodiment may have a configuration in which the shift of the microlens continuously becomes larger. In other words, the light emitting apparatus according to the present exemplary embodiment includes the fifth light emitting element that is arranged between the first light emitting element and the second light emitting element and adjacent to the second light emitting element, and the fifth lens that light emitted by the fifth light emitting element enters. In the light emitting apparatus according to the present exemplary embodiment, in the cross section vertical to the principal surface, the distance between the midpoint of the light emitting region of the fifth light emitting element and the vertex of the fifth lens in the direction parallel to the principal surface may be smaller than the distance between the midpoint of the light emitting region of the second light emitting element and the vertex of the second lens in the direction parallel to the principal surface. In the cross section vertical to the principal surface, the distance between the midpoint of the light emitting region of the fifth light emitting element and the vertex of the fifth lens in the direction parallel to the principal surface may be larger than the distance between the midpoint of the light emitting region of the first light emitting element and the vertex of the first lens in the direction parallel to the principal surface.

In this case, the light emitting region of the fifth light emitting element is larger in size than the light emitting region of the second light emitting element, and smaller in size than the light emitting region of the first light emitting element.

On the other hand, the light emitting apparatus according to the present exemplary embodiment includes the sixth light emitting element adjacent to the second light emitting element, and the sixth lens that light emitted by the sixth light emitting element enters, and the second light emitting element is arranged between the first light emitting element and the sixth light emitting element. In the light emitting apparatus according to the present exemplary embodiment, in the cross section vertical to the principal surface, a distance between the midpoint of the light emitting region of the sixth light emitting element and the vertex of the sixth lens in the direction parallel to the principal surface may be larger than the distance between the midpoint of the light emitting region of the second light emitting element and the vertex of the second lens in the direction parallel to the principal surface.

In this case, the light emitting region of the sixth light emitting element is smaller in size than the light emitting region of the second light emitting element.

The light emitting elements that emit the second light include a seventh light emitting element that is arranged between the third light emitting element and the fourth light emitting element and adjacent to the fourth light emitting element, and a seventh lens that light emitted by the seventh light emitting element enters. In the cross section vertical to the principal surface, a distance between a midpoint of a light emitting region of the seventh light emitting element and a vertex of the seventh lens in the direction parallel to the principal surface is smaller than the distance between the midpoint of the light emitting region of the fourth light emitting element and the vertex of the fourth lens in the direction parallel to the principal surface. In the cross section vertical to the principal surface, the distance between the midpoint of the light emitting region of the seventh light emitting element and the vertex of the seventh lens in the direction parallel to the principal surface is larger than the distance between the midpoint of the light emitting region of the third light emitting element and the vertex of the third lens in the direction parallel to the principal surface.

In this case, the light emitting region of the seventh light emitting element is smaller in size than the light emitting region of the third light emitting element, and larger in size than the light emitting region of the fourth light emitting element.

### Effect of Reducing Color Shift According to Present Exemplary Embodiment

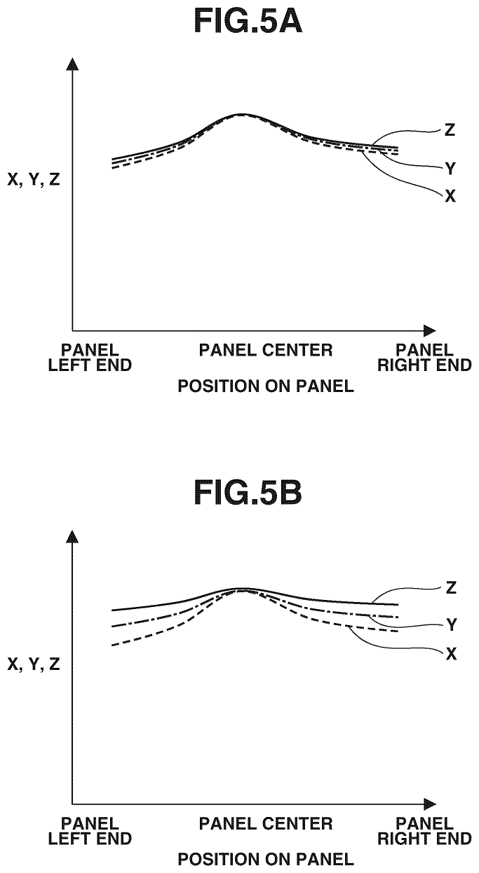

FIGS. 5A and 5B are graphs illustrating tristimulus values that are standardized based on positions in a display region in the light emitting apparatus. A vertical axis indicates a tristimulus value, and a horizontal axis indicates a position on a panel. FIG. 5A is a graph illustrating standardized tristimulus values in a case where the light emitting region 109 of a light emitting element that emits light with the second color is smaller than the light emitting region 108 of a light emitting element that emits light with the first color. A difference in tristimulus value is reduced at the outer peripheral portion of the display region, the right end of the panel, and the left end of the panel. In other words, a color shift is reduced. By making the light emitting region 109 of a light emitting element that emits light with the second color smaller than the light emitting region 108 of a light emitting element that emits light with the first color, a variation in viewing angle characteristics among the colors is reduced, and a difference in luminance among the colors on the display surface is reduced.

On the other hand, FIG. 5B is a graph illustrating standardized tristimulus values in a case where the light emitting region 109 of the light emitting element that emits light with the second color and the light emitting region 108 of the light emitting element that emits light with the first color have the same size. A difference in tristimulus value is observed at the outer peripheral portion of the display region, the right end of the panel, and the left end of the panel. In other words, a color shift cannot be reduced. In a center region located at the central portion of the display region, light rays traveling toward the front direction with respect to the display surface are used. In contrast to this, in an outer peripheral region located at the outer peripheral portion of the display region, light rays traveling in the oblique direction with respect to the display surface are used. Due to a variation in viewing angle characteristics among the colors, luminance varies for each color on the display surface.

### Third Exemplary Embodiment

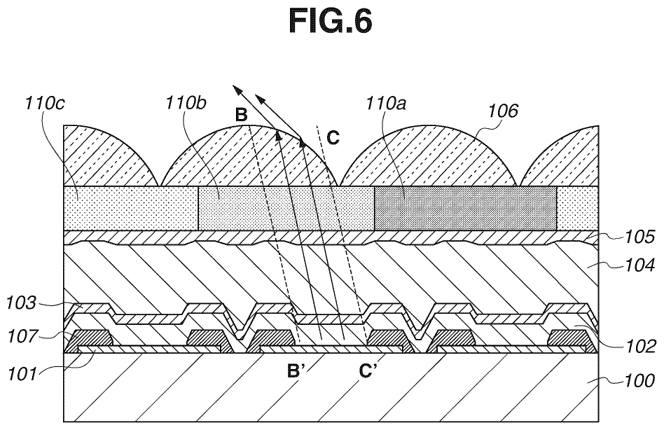

FIG. 6 is a schematic cross-sectional view illustrating a light emitting apparatus according to a third embodiment of the present invention. In addition to the components described in the first exemplary embodiment, color filters 110a to 110c are arranged on the planarization layer 105. Respective pixels including the color filters 110a to 110c can be regarded as subpixels, and the three subpixels can be regarded as one main pixel. The subpixels are not limited to red (R), green (G) and blue (B) pixels. For example, a white light emitting element and a yellow light emitting element may be provided. In the case of the white light emitting element, a transparent filter may be used as a color filter, or a filter may be omitted. It is especially desirable that the subpixels are red, green and blue pixels, and full-color display can be implemented by additive color mixing of these subpixels.

The planar array of subpixels may be any array of a stripe array, a square array, a delta array, or a Bayer array. By arranging main pixels in a matrix, it is possible to provide a display apparatus with a high pixel count.

Similarly to the microlens 106, the color filters 110a to 110c are also arranged so as to be shifted from the center of the light emitting region 108b. At this time, the color filter 110b may be provided on a line connecting a vertex B of the microlens 106 and an end B′ on the first light emitting element side of the light emitting region.

The color filter 110b is provided on a line connecting an end C of the microlens and an end C′ of the light emitting region. At least two types of color filters may be arranged on a line segment connecting a vertex of the microlens immediately above the light emitting region 108b and a light emitting region adjacent to the light emitting region 108b. The light emission from the adjacent light emitting region is to reduce light emission from an unintended microlens.

Because light emitted from the light emitting region 108b passes through the color filter 110b, can be refracted in the oblique direction by the microlens 106, and does not pass through the color filters 110a and 110c of the other subpixels, color purity can be enhanced.

### Design of Microlens According to Present Exemplary Embodiment

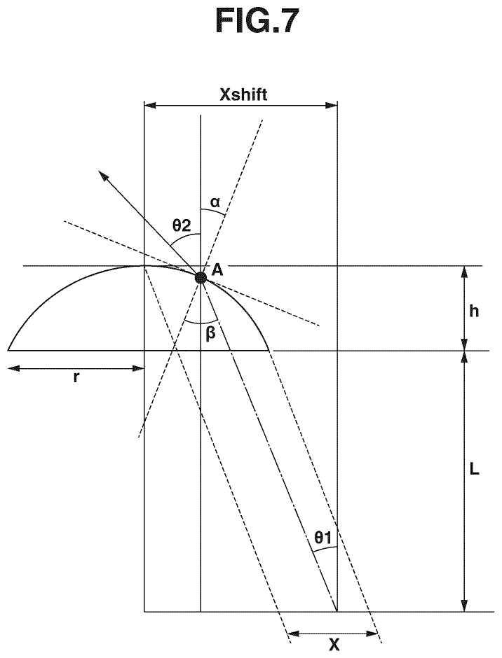

FIG. 7 is a cross-sectional view illustrating a relationship between the light emitting region 108 of a light emitting element that emits light with the first color, the light emitting region 109 of a light emitting element that emits light with the second color, and the microlens 106.

In FIG. 7, the microlens 106 having a height h, a radius r, and a refractive index n is formed.

Light is emitted at an angle θ1 from the light emitting region 108 of the light emitting element that emits light with the first color, and the light is refracted at an angle θ2 at a point A of the microlens 106. At this time, a gradient with respect to a tangent line of the microlens 106 at the point A is assumed to be an angle α. The following formula (1) is satisfied according to the Snell's law. In FIG. 7, α+1 is describe as β.

$$1 \times sin ( ηθ2 + α ) = n \times sin ( α + θ1 ) \qquad ( 1 )$$

If Formula (1) is solved for θ1, θ1 is represented by Formula (2).

$$θ1 = {sin}^{- 1} \{ sin ( θ2 + α ) / n \} - α \qquad ( 2 )$$

If a shift amount of the vertex of the microlens 106 from the center of the light emitting region 108 is denoted by Xshift, and a distance from the light emitting region 108 to the microlens 106 is denoted by L, a size X of the light emitting region 108 is represented by the following formula (3).

$$X = r - h \times tan ( θ1 ) \qquad ( 3 )$$

From Formulae (2) and (3), the size X of the light emitting region 108 is represented by Formula (4).

$$X = r - h \times tan [ {sin}^{- 1} \{ sin ( θ2 + α ) / n \} - α ] \qquad ( 4 )$$

At this time, a relationship between the angle θ1 of light emitted from the light emitting region 108 and the shift amount Xshift of the vertex of the microlens 106 from the center of the light emitting region 108 is represented by Formula (5).

$${tan}^{- 1} ( Xshift / h + L ) > θ1 \qquad ( 5 )$$

In the calculation executed according to wave optics simulation, a shift amount of the vertex of the microlens 106 from the center of the light emitting region 108 of the light emitting element that emits light with the first color, and an aperture ratio of the light emitting region are obtained as a result, as shown in Table 1. By setting a shift amount from the center of the light emitting region 109 of the light emitting element that emits light with the second color, and an aperture ratio of the light emitting region to values smaller than those in Table 1, a color shift attributed to a viewing angle is reduced.

Nevertheless, actually, other members such as the protective layer 104 and the color filters 110a to 110c also exist between the microlens 106 and the light emitting region 108, and thus an error might be generated.

TABLE 1

| Distance between Vertex of | Aperture |
|---|---|
| Microlens and Center of Light | Ratio of Light |
| Emitting Region | Emitting Region |
| 0 micrometer (μm) | 50% |
| 0.5 μm | 46% |
| 1.0 μm | 40% |
| 1.5 μm | 33% |

In the light emitting apparatus according to the present exemplary embodiment, as a distance between a vertex of a microlens and a center of a light emitting region becomes smaller, an aperture ratio becomes larger. In addition, as a distance between a vertex of a microlens and a center of a light emitting region becomes smaller, lens efficiency becomes smaller, and as a distance between a vertex of a microlens and a center of a light emitting region becomes larger, lens efficiency becomes larger. The lens efficiency refers to a ratio between luminance obtainable in a case where a lens is not included, and luminance obtainable in a case where a lens is included, at an arbitrary angle. If a sweet spot does not increase in a case where a size of the light emitting region increases, a region not contributing to light emission increases, and lens efficiency becomes smaller. In a case where a distance between a vertex of a microlens and a midpoint of a light emitting region becomes larger in wide-angle light, if light deviates from the sweet spot, lens efficiency becomes smaller. The lens efficiency may be estimated at an angle of 45 degrees with respect to an optical axis of a lens.

In other words, the light emitting apparatus according to the present exemplary embodiment includes a substrate having a principal surface, a first light emitting element, a second light emitting element, a third light emitting element and a fourth light emitting element that are arranged on the principal surface, a first lens that light emitted by the first light emitting element enters, a second lens that light emitted by the second light emitting element enters, a third lens that light emitted by the third light emitting element enters, and a fourth lens that light emitted by the fourth light emitting element enters, in which the first light emitting element and the second light emitting element emit first light, and the third light emitting element and the fourth light emitting element emit second light in a wavelength different from that of the first light. It can be said that, in a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface, a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface, a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface, the first lens has lens efficiency smaller than that of the second lens, the third lens has lens efficiency smaller than that of the fourth lens, and the fourth lens has lens efficiency smaller than that of the second lens. The wavelength of the first light may be shorter than the wavelength of the second light. In other words, if the first light is blue, the second light may be green or red.

### Another Configuration in Exemplary Embodiment

### Configuration of Organic Light Emitting Element

In an organic light emitting element, an insulating layer, a first electrode, an organic compound layer, and a second electrode are formed and provided on a substrate. A protective layer, a color filter, a microlens and the like may be provided on the negative electrode. In a case where a color filter is provided, a planarization layer may be provided between the color filter and the protective layer. The planarization layer can be made of acrylic resin. The same applies to a case where a planarization layer is provided between the color filter and the microlens.

### [Substrate]

Examples of the material of the substrate include quartz, glass, a silicon wafer, resin, and metal. In addition, a switching element, such as a transistor and wiring, may be provided on the substrate, and the insulating layer may be provided thereon. The material of the insulating layer is not limited as long as a contact hole can be formed in such a manner that wiring can be formed between the insulating layer and the first electrode, and insulation of a wire not to be connected can be ensured. For example, resin such as polyimide, silicon oxide, or silicon nitride can be used.

### [Electrode]

As electrodes, a pair of electrodes can be used. The pair of electrodes may be a positive electrode and a negative electrode. In the case of applying an electrical field in a direction in which the organic light emitting element emits light, an electrode with high potential serves as a positive electrode, and the other electrode serves as a negative electrode. It can also be said that an electrode that supplies a hole to a light emitting layer serves as a positive electrode, and an electrode that supplies an electron serves as a negative electrode.

The constituent material of the positive electrode is desirably a material having a as large work function as possible. For example, an elementary metal, such as gold, platinum, silver, copper, nickel, palladium, cobalt, selenium, vanadium, or tungsten, a composite containing these, an alloy formed by combining these, or a metal oxide, such as tin oxide, zinc oxide, indium oxide, indium tin oxide (ITO), or indium zinc oxide, can be used. In addition, a conductive polymer such as polyaniline, polypyrrole, or polythiophene can also be used.

Among these electrode materials, a single type of material may be used alone, or two or more types of material may be used in combination. In addition, the positive electrode may have a single-layer structure, or may have a multilayered structure.

In a case where an electrode is used as a reflective electrode, for example, chromium, aluminum, silver, titanium, tungsten, molybdenum, an alloy formed by mixing these or a lamination formed by these can be used. Using the above-described material, an electrode may function as a reflective film not having a function as an electrode. In a case where an electrode is used as a transparent electrode, an oxide transparent conductive layer such as indium tin oxide (ITO) or indium zinc oxide can be used, but the material of the electrode is not limited to these. A photolithography technique can be used for the formation of electrodes.

On the other hand, the constituent material of the negative electrode is desirably a material having a small work function. For example, an elementary metal, such as alkali metal (e.g., lithium), alkaline earth metal (e.g., calcium), aluminum, titanium, manganese, silver, lead, or chromium, a composite containing these can be used. Alternatively, an alloy formed by combining these individual metals can also be used. For example, magnesium-silver, aluminum-lithium, aluminum-magnesium, silver-copper, or zinc-silver can be used. Metal oxide such as indium tin oxide (ITO) can also be used. Among these electrode materials, a single type of material may be used alone, or two or more types of material may be used in combination. In addition, the negative electrode may have a single-layer structure, or may have a multilayered structure. Among these, it is desirable to use silver, and to reduce the agglomeration of silver, it is more desirable to use a silver alloy. As long as the agglomeration of silver can be reduced, a ratio of silver in the alloy is not limited. For example, a ratio between silver and another type of metal may be 1:1 or 3:1.

The negative electrode may function as a top emission element using an oxide conductive layer such as ITO, or may function as a bottom top emission element using a reflective electrode such as aluminum (Al), and the function of the negative electrode is not specifically limited. The formation method of the negative electrode is not specifically limited, but it is desirable to use direct-current and alternating-current sputtering methods because good coverage of a film can be obtained, and resistance can be easily decreased.

### [Organic Compound Layer]

An organic compound layer may have a single-layer structure, or may have a multilayered structure. In a case where the organic compound layer has a multilayered structure, the organic compound layer may be called a hole-injecting layer, a hole transport layer, an electron blocking layer, a light emitting layer, a hole blocking layer, an electron transport layer, or an electron-injection layer, depending on its function. The organic compound layer is mainly formed of an organic compound, but may contain an inorganic atom or an inorganic compound. For example, the organic compound layer may contain copper, lithium, magnesium, aluminum, iridium, platinum, molybdenum, or zinc. The organic compound layer may be arranged between the first electrode and the second electrode, or may be arranged in contact with the first electrode and the second electrode.

### [Protective Layer]

A protective layer may be provided on the negative electrode. For example, by bonding glass provided with a moisture absorption agent onto the negative electrode, the intrusion of water into the organic compound layer can be reduced, and the occurrence of a display failure can be reduced. As another exemplary embodiment, the intrusion of water into the organic compound layer may be reduced by providing a passivation film such as silicon nitride on the negative electrode. For example, after the negative electrode is formed, the organic light emitting element is transported to another chamber without breaking the vacuum, and then a protective layer may be formed thereon by forming a silicon nitride film with a thickness of 2 micrometers (μm) by a chemical vapor deposition (CVD) method. After a film is formed using the CVD method, a protective layer may be provided using an atomic layer deposition method (ALD method). The material of a film to be formed using the ALD method is not limited, but may be silicon nitride, silicon oxide, aluminum oxide or the like. On the film formed using the ALD method, silicon nitride may be further formed using the CVD method. The film thickness of the film formed using the ALD method may be smaller than that of the film formed using the CVD method. Specifically, the film thickness may be equal to or smaller than 50%, and furthermore, may be equal to or smaller than 10%.

### [Color Filter]

A color filter may be provided on the protective layer. For example, a color filter formed in consideration of the size of the organic light emitting element may be provided on a different substrate, and this substrate may be bonded to the substrate on which the organic light emitting element is provided, or patterning of color filters may be performed on the above-described protective layer using the photolithography technique. The color filters may be made of high molecular material.

### [Planarization Layer]

A planarization layer may be provided between the color filter and the protective layer. The planarization layer is provided for the purpose of reducing the unevenness of a lower layer. In some cases, the planarization layer is called a material resin layer without limiting its purpose. The planarization layer may be made of an organic compound, and may be made of whichever of a low molecular material and a high molecular material, but is desirably made of a high molecular material.

Planarization layers may be provided on and below the color filter, and the constituent materials of the planarization layers may be the same or different. Specifically, examples of the constituent materials include polyvinyl carbazole resin, polycarbonate resin, polyester resin, acrylonitrile butadiene styrene (ABS) resin, acrylic resin, polyimide resin, phenol resin, epoxy resin, silicon resin, and urea resin.

### [Microlens]

The light emitting apparatus may include an optical member such as a microlens on its light emission side. The microlens can be made of acrylic resin or epoxy resin. The microlens is provided for the purpose of increasing an amount of light to be extracted from the light emitting apparatus, and controlling the direction of light to be extracted. The microlens may have a hemispherical shape. In a case where the microlens has a hemispherical shape, among tangent lines in contact with the hemisphere, there is a tangent line parallel to the insulating layer, and a contact point between the tangent line and the hemisphere corresponds to a vertex of the microlens. The vertex of the microlens can be determined in any cross-sectional view in the similar manner. That is, among tangent lines in contact with the semicircle of the microlens in a cross-sectional view, there is a tangent line parallel to the insulating layer, and a contact point between the tangent line and the semicircle corresponds to the vertex of the microlens.

A midpoint of the microlens can also be defined. In a cross section of the microlens, an imaginary line segment from a point at which the shape of an arc ends to a point at which the shape of another arc ends is set, and a midpoint of the imaginary line segment can be called a midpoint of the microlens. The cross section in which the vertex and the midpoint are determined may be a cross section vertical to the insulating layer.

### [Counter Substrate]

A counter substrate may be provided on the planarization layer. Because the counter substrate is provided at a position facing the above-described substrate, it is referred to as a counter substrate. The constituent material of the counter substrate may be the same as that of the above-described substrate. In a case where the above-described substrate is assumed to be a first substrate, the counter substrate may be regarded as a second substrate.

### [Organic Layer]

The organic compound layer (a hole-injecting layer, a hole transport layer, an electron blocking layer, a light emitting layer, a hole blocking layer, an electron transport layer, an electron-injection layer, etc.) included in the organic light emitting element according to an exemplary embodiment of the present invention is formed using the following method.

For the formation of the organic compound layer included in the organic light emitting element according to an exemplary embodiment of the present invention, a dry process such as a vacuum deposition method, an ionized deposition method, sputtering method, or a plasma method can be used. Instead of the dry process, a wet process of forming a layer by applying a solution using an appropriate solvent by using a known coating method (e.g., spin coating, dipping, a casting method, a Langmuir-Blodgett (LB) method, an inkjet method, etc.) can also be used.

If a layer is formed using the vacuum deposition method or a solution coating method, crystallization is less likely to occur in the layer, and high temporal stability can be obtained. In the case of forming a film using a coating method, the film can be formed in combination with an appropriate binder resin.

Examples of the above-described binder resin include polyvinyl carbazole resin, polycarbonate resin, polyester resin, ABS resin, acrylic resin, polyimide resin, phenol resin, epoxy resin, silicon resin, and urea resin, but the binder resin is not limited to these.

Among these binder resins, a single type of binder resin may be used along as a homopolymer or a copolymer, or two or more types of binder resin may be mixed and used. Furthermore, as necessary, a known additive agent, such as a plasticizer, an antioxidant, or an ultraviolet absorber, may be used in combination.

### [Pixel Circuit]

The light emitting apparatus may include a pixel circuit connected to the light emitting element. The pixel circuit may be an active-matrix circuit that controls the light emission of a first light emitting element and a second light emitting element independently. The active-matrix circuit may be whichever of a voltage-programmed pixel circuit and a current-programmed pixel circuit. A drive circuit includes a pixel circuit for each pixel. The pixel circuit may include a light emitting element, a transistor that controls the emission luminance of the light emitting element, a transistor that controls a light emission timing, a capacitance that holds a gate voltage of the transistor that controls the emission luminance, and a transistor for connecting to the ground (GND) not via the light emitting element.

The light emitting apparatus includes a display region, and a peripheral region arranged around the display region. The display region includes a pixel circuit, and the peripheral region includes a display control circuit. The mobility of a transistor included in the pixel circuit may be smaller than the mobility of a transistor included in the display control circuit.

The gradient of the current-voltage characteristic of the transistor included in the pixel circuit may be smaller than the gradient of the current-voltage characteristic of the transistor included in the display control circuit. The gradient of the current-voltage characteristic can be measured based on so-called Vg-Ig characteristics.

The transistor included in the pixel circuit is a transistor connected to a light emitting element such as the first light emitting element.

The magnitude of a drive current may be determined in accordance with the size of a light emitting region. Specifically, in the case of causing the first light emitting element and the second light emitting element to emit light at the same luminance, a value of a current cause to flow in the first light emitting element may be smaller than a value of a current caused to flow in the second light emitting element. This is because required current is small since the size of the light emitting region is small in some cases.

### [Pixel]

The light emitting apparatus includes a plurality of pixels. Pixels include subpixels that emit light with colors different from each other. Subpixels may have RGB light emission colors, for example.

In the pixel, a region also called a pixel aperture emits light. This region is the same as a first region. The pixel aperture may be equal to or smaller than 15 μm, and may be equal to or larger than 5 μm. More specifically, the pixel aperture may be 11 μm, 9.5 μm, 7.4 μm, or 6.4 μm.

An interval between subpixels may be equal to or smaller than 10 μm. Specifically, an interval between subpixels may be 8 μm, 7.4 μm, or 6.4 μm.

Pixels can employ a known arrangement configuration in a plan view. For example, the arrangement may be stripe arrangement, delta arrangement, Pentile arrangement, or Bayer arrangement. The shape of the subpixels in a plan view may be any of known shapes. For example, the shape may be a quadrangle such as a rectangle or a rhomboid, or a hexagon. Needless to say, a shape that is not an exact rectangle and resembles a rectangle is included in rectangles. The shape of subpixels and a pixel array can be used in combination.

### Use Application of Organic Light Emitting Element According to Exemplary Embodiment of Present Invention

The organic light emitting element according to an exemplary embodiment of the present invention can be used as a component of a display apparatus or an illumination apparatus. Aside from these, the use applications include an exposure light source of an electrophotographic image forming apparatus, a backlight of a liquid crystal display apparatus, and a light emitting apparatus including a color filter in a white light source.

The display apparatus may be an image information processing apparatus that includes an image input unit that inputs image information from an area charge-coupled device (CCD), a linear CCD, or a memory card, and an information processing unit that processes the input information, and displays an input image on a display unit.

A display unit included in an imaging apparatus or an inkjet printer may have a touch panel function. A driving method of this touch panel function is not specifically limited, and the touch panel may be whichever of an infrared touch panel, a capacitive touch panel, a resistive touch panel, and an electromagnetic touch panel. The display apparatus may be used in a display unit of a multifunctional printer.

Next, a display apparatus according to the present exemplary embodiment will be described with reference to the drawings.

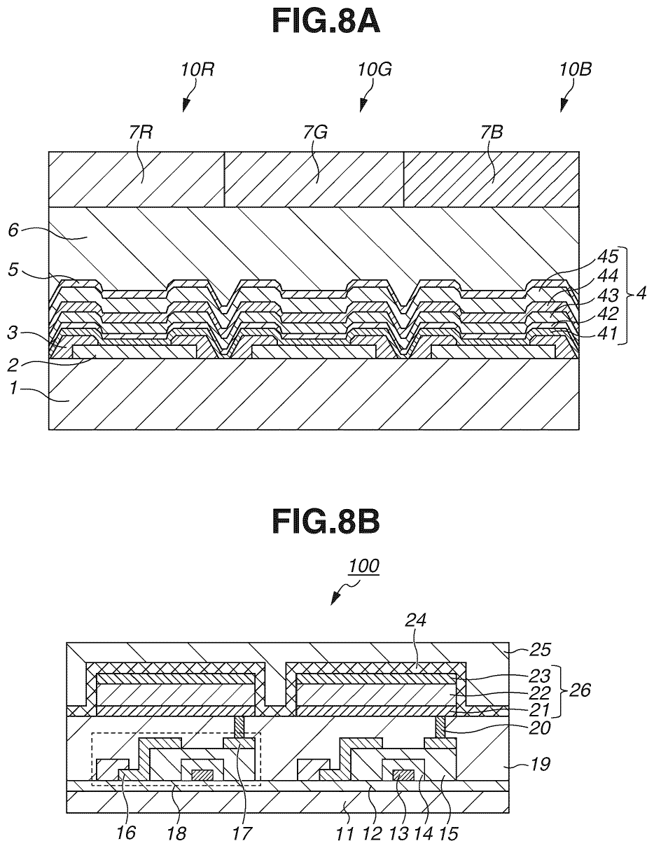

FIGS. 8A and 8B are schematic cross-sectional views illustrating an example of a display apparatus including an organic light emitting element and a transistor connected to this organic light emitting element. The transistor is an example of an active element. The transistor may be a thin-film transistor (TFT).

FIG. 8A illustrates an example of a pixel that is a component included in the display apparatus according to the present exemplary embodiment. The pixel includes subpixels 10. The subpixels 10 are classified into subpixels 10R, 10G, and 10B based on their light emission. Light emission colors may be distinguished based on the wavelength of light emitted from each light emitting layer, or light emitted from subpixels may be selectively filtered or converted using color filters. Each subpixel includes a reflective electrode 2 serving as a first electrode, an insulating layer 3 covering the ends of the reflective electrode 2, an organic compound layer 4 covering the first electrode and the insulating layer 3, a transparent electrode 5, a protective layer 6, and color filters 7, which are provided above the interlayer insulating layer 1.

A transistor and a capacitive element may be arranged in the interlayer insulating layer 1 or in a lower layer below the interlayer insulating layer 1. The transistor and the first electrode may be electrically connected via a contact hole (not illustrated).

The insulating layer 3 is also called a bank or a pixel isolation film. The insulating layer 3 covers the ends of the first electrode, and is arranged to surround the first electrode. A portion in which the insulating layer 3 is not arranged is in contact with the organic compound layer 4, and serves as a light emitting region.

The organic compound layer 4 includes a hole-injecting layer 41, a hole transport layer 42, a first light emitting layer 43, a second light emitting layer 44, and an electron transport layer 45.

The second electrode 5 may be whichever of a transparent electrode, a reflective electrode, and a semi-transmissive electrode.

The protective layer 6 reduces the intrusion of moisture into the organic compound layer 4. The protective layer 6 is illustrated as one layer in FIG. 8A, but may have a multilayered structure. The protective layer 6 may include an inorganic compound layer and an organic compound layer in each layer.

The color filters 7 are classified into color filters 7R, 7G, and 7B based on their colors. The color filters 7 may be formed on a planarization layer (not illustrated). In addition, a resin protective layer (not illustrated) may be provided on the color filters 7. The color filters 7 may be formed on the protective layer 6. Alternatively, after the color filters 7 are provided on a counter substrate such as a glass substrate, the substrate may be bonded to the protective layer 6.

In a display apparatus 100 illustrated in FIG. 8B, an organic light emitting element 26 and a TFT 18 serving as an example of a transistor are included. A substrate 11 such as a glass substrate or a silicon substrate is provided, and an insulating layer 12 is provided thereon. An active element such as the TFT 18 is arranged on the insulating layer 12, and a gate electrode 13 of the active element, a gate insulating film 14, and a semiconductor layer 15 are arranged. Aside from these, the TFT 18 includes the semiconductor layer 15, a drain electrode 16 and a source electrode 17. An insulating film 19 is provided above the TFT 18. A positive electrode 21 included in an organic light emitting element 26 and a source electrode 17 are connected via a contact hole 20 provided in the insulating film 19.

The electric connection method of an electrode (positive electrode, negative electrode) included in an organic light emitting element 26, and an electrode (source electrode, drain electrode) included in the TFT 18 is not limited to the method illustrated in FIG. 1B. That is, any connection method may be employed as long as either one of the positive electrode and the negative electrode of the organic light emitting element 26 and either one of the source electrode and the drain electrode of the TFT 18 are electrically connected. The TFT stands for a thin-film transistor.

In the display apparatus 100 illustrated in FIG. 8B, an organic compound layer 22 is illustrated as one layer, but the organic compound layer 22 may have a multilayers structure. A first protective layer 24 and a second protective layer 25 for reducing a deterioration of the organic light emitting element are provided on a negative electrode 23.

In the display apparatus 100 illustrated in FIG. 8B, a transistor is used as a switching element, but the transistor may be used as another switching element instead of this.

The transistor used in the display apparatus 100 illustrated in FIG. 8B is not limited to a transistor that uses a monocrystal silicon wafer, and may be a thin-film transistor including an active layer on an insulating surface of the substrate 11. Examples of the active layer include monocrystal silicon, amorphous silicon, non-monocrystal silicon such as microcrystal silicon, and a non-monocrystalline oxide semiconductor such as indium zinc oxide and indium gallium zinc oxide. The thin-film transistor is also called a TFT element.

The transistor included in the display apparatus 100 illustrated in FIG. 8B may be formed in a substrate such as a silicon (Si) substrate. Forming the transistor in the substrate means preparing the transistor by processing the substrate such as a Si substrate. That is, a state in which the transistor is included in the substrate can be regarded as a state in which the substrate and the transistor are integrally formed.

The light emission luminance of the organic light emitting element according to the present exemplary embodiment is controlled by the TFT serving as an example of a switching element, and by providing a plurality of organic light emitting elements within a surface, it is possible to display an image at each light emission luminance. The switching element according to the present exemplary embodiment is not limited to the TFT, and may be a transistor made of low-temperature polysilicon, or an active matrix driver formed on a substrate such as a Si substrate. The term “on the substrate” includes “in the substrate.” Whether to provide a transistor in a substrate or to use the TFT is selected depending on the size of a display unit. For example, if the size of the display unit is about 0.5 inches, it is desirable to provide an organic light emitting element on the Si substrate.

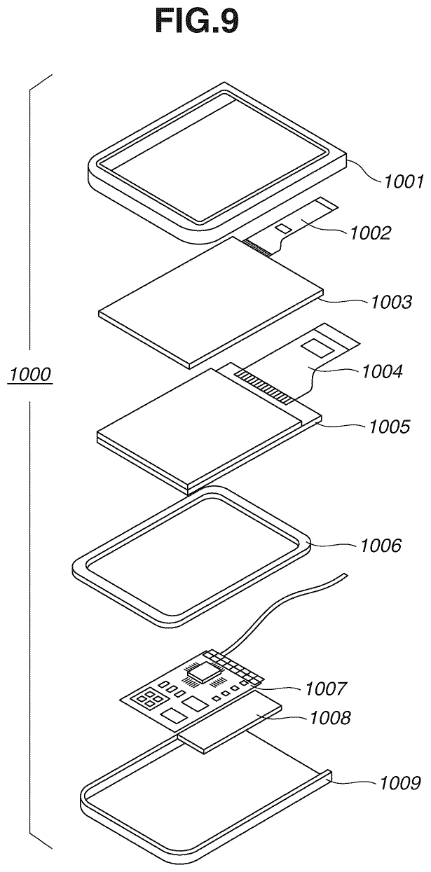

FIG. 9 is a schematic diagram illustrating an example of a display apparatus according to the present exemplary embodiment. A display apparatus 1000 may include an upper cover 1001 and a lower cover 1009, and may further include a touch panel 1003, a display panel 1005, a frame 1006, a circuit board 1007, and a battery 1008 between the upper cover 1001 and the lower cover 1009. Flexible printed circuits (FPCs) 1002 and 1004 are connected to the touch panel 1003 and the display panel 1005, respectively. A transistor is printed on the circuit board 1007. The battery 1008 may be omitted if the display apparatus 1000 is not a portable device. If the display apparatus 1000 is a portable device, the battery 1008 may be provided at another position.

The display apparatus 1000 according to the present exemplary embodiment may include color filters of a red color, a green color, and a blue color. The color filters of the red color, the green color and the blue colors may be arranged in a delta array.

The display apparatus 1000 according to the present exemplary embodiment may be used in a display unit of a mobile terminal. In this case, the display apparatus 1000 may have both of a display function and an operation function. Examples of the mobile terminal include a mobile phone such as a smartphone, a tablet, and a head-mounted display.

The display apparatus 1000 according to the present exemplary embodiment may be used in a display unit of an imaging apparatus including an optical unit including a plurality of lenses and an image sensor that receives light having passed through the optical unit. The imaging apparatus may include a display unit that displays information acquired by the image sensor. The display unit may be whichever of a display unit exposed to the outside of the imaging apparatus, and a display unit arranged within a viewfinder. The imaging apparatus may be a digital camera or a digital video camera.

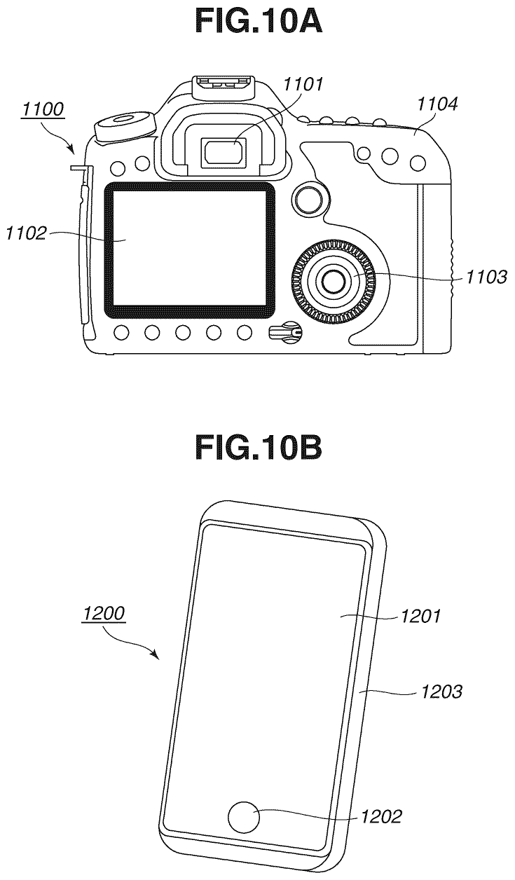

FIG. 10A is a schematic diagram illustrating an example of an imaging apparatus according to the present exemplary embodiment. An imaging apparatus 1100 may include a viewfinder 1101, a back-surface display 1102, an operation unit 1103, and a housing 1104. The viewfinder 1101 may include the display apparatus according to the present exemplary embodiment. In this case, the display apparatus may display not only a captured image but also environmental information and an image capturing instruction. The environmental information may include the intensity of external light, the orientation of external light, a speed at which a subject is moving, and a possibility that a subject will be shielded by a shielding object.

Because a timing desirable for image capturing is a short amount of time, it is desirable to display information as quickly as possible. Accordingly, it is desirable to use a display apparatus that uses the organic light emitting element according to an exemplary embodiment of the present invention. This is because the organic light emitting element has a high response speed. The display apparatus that uses the organic light emitting element can be used more desirably for an apparatus that requires a high display speed than a liquid crystal display apparatus.

The imaging apparatus 1100 may further include an optical unit (not illustrated). The optical unit includes a plurality of lenses and forms an image on an image sensor accommodated in the housing 1104. By adjusting relative positions of the plurality of lenses, it is possible to control a focal point. This operation can also be performed automatically. The imaging apparatus may be called a photoelectric conversion apparatus. An image capturing method for the photoelectric conversion apparatus can include a method of detecting a difference from a previous image instead of sequentially capturing images, and a method of clipping an image from constantly-recorded images.

FIG. 10B is a schematic diagram illustrating an example of an electronic device according to the present exemplary embodiment. An electronic device 1200 includes a display unit 1201, an operation unit 1202, and a housing 1203. The housing 1203 may house a circuit, a printed substrate including the circuit, a battery, and a communication unit. The operation unit 1202 may be a button or may be a touch panel type response unit. The operation unit 1202 may be a biometric authentication unit that unlocks the electronic device 1200 by recognizing a fingerprint. The electronic device 1200 including a communication unit can also be called a communication device. The electronic device 1200 may further include a lens and an image sensor and thus may have a camera function. An image captured using the camera function is displayed on the display unit 1201. Examples of the electronic device 1200 include a smartphone and a laptop personal computer.

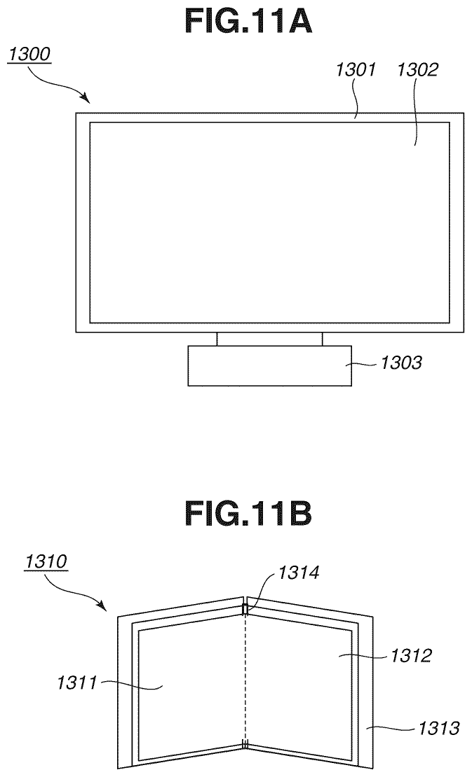

FIGS. 11A and 11B are schematic diagrams illustrating an example of a display apparatus according to the present exemplary embodiment. FIG. 11A illustrates a display apparatus 1300 such as a television monitor or a personal computer (PC) monitor. The display apparatus 1300 includes a frame 1301 and a display unit 1302. The light emitting apparatus according to the present exemplary embodiment may be used in the display unit 1302.

The display apparatus 1300 further includes a base 1303 supporting the frame 1301 and the display unit 1302. The configuration of the base 1303 is not limited to the configuration illustrated in FIG. 11A. A lower side of the frame 1301 may also serve as a base.

The frame 1301 and the display unit 1302 may have a curved shape. The curvature radius of the curved shape may be 5000 millimeters (mm) or more and 6000 mm or less.

FIG. 11B is a schematic diagram illustrating another example of the display apparatus according to the present exemplary embodiment. A display apparatus 1310 illustrated in FIG. 11B has a configuration in which its display surface is foldable, and is a so-called foldable display apparatus. The display apparatus 1310 includes a first display unit 1311, a second display unit 1312, a housing 1313, and a folding point 1314. The first display unit 1311 and the second display unit 1312 may include the light emitting apparatus according to the present exemplary embodiment. The first display unit 1311 and the second display unit 1312 may form a seamless display apparatus. The first display unit 1311 and the second display unit 1312 can be divided at the folding point 1314. The first display unit 1311 and the second display unit 1312 may display respective different images, or the first display unit 1311 and the second display unit 1312 may display one image in cooperation.

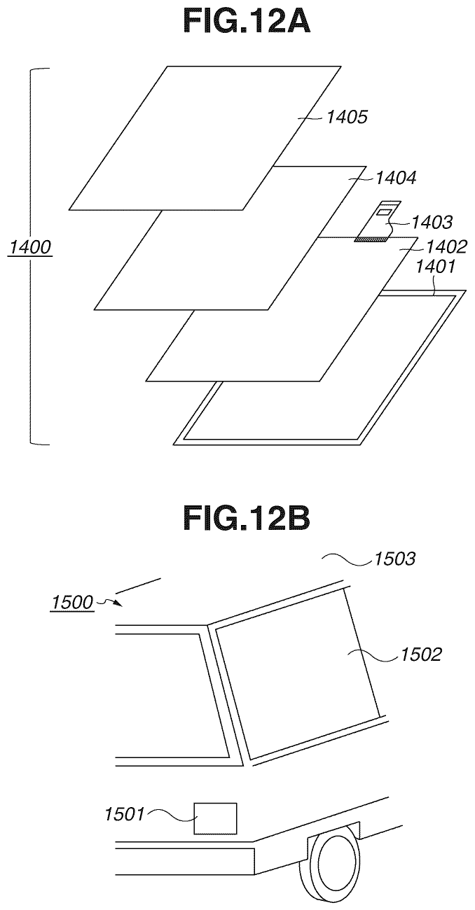

FIG. 12A is a schematic diagram illustrating an example of an illumination apparatus according to the present exemplary embodiment. An illumination apparatus 1400 may include a housing 1401, a light source 1402, a circuit board 1403, an optical filter 1404, and a light diffusion unit 1405. The light source 1402 may include the organic light emitting element according to the present exemplary embodiment. The optical filter 1404 may be a filter that enhances color rendering properties of the light source 1402. The light diffusion unit 1405 can effectively diffuse light from the light source 1402 by lighting up, and can deliver light to a wide range. The optical filter 1404 and the light diffusion unit 1405 may be provided on a light emission side in the illumination apparatus 1400. A cover may be provided as necessary at an outermost portion.

The illumination apparatus 1400 is an apparatus that illuminates the inside of a room, for example. The illumination apparatus 1400 may emit light with any color of a white color, a natural white color, and other colors from blue to red. The illumination apparatus 1400 may include a light control circuit for controlling these colors. The illumination apparatus 1400 may include a light control circuit for controlling these colors. The illumination apparatus 1400 may include the organic light emitting element according to an exemplary embodiment of the present invention, and a power circuit connected to the organic light emitting element. The power circuit is a circuit that converts an alternating-current voltage into a direct-current voltage. In addition, a color temperature of the white color is 4200 K and a color temperature of the natural white color is 5000 K. The illumination apparatus 1400 may include a color filter.

The illumination apparatus 1400 according to the present exemplary embodiment may also include a heat release unit. The heat release unit releases heat in the apparatus to the outside of the apparatus, and metal or liquid silicon with high specific heat can be used.

FIG. 12B is a schematic diagram illustrating an automobile serving as an example of a movable body according to the present exemplary embodiment. The automobile includes a tail lamp serving as an example of an illumination device. An automobile 1500 may include a tail lamp 1501, and may be configured to light the tail lamp 1501 when a brake operation is performed.

The tail lamp 1501 may include the organic light emitting element according to the present exemplary embodiment. The tail lamp 1501 may include a protection member that protects an organic electroluminescence (EL) element. The material of the protection member is not limited as long as the protection member is transparent and has a relatively high level of strength, but it is desirable that the protection member is made of polycarbonate. A furandicarboxylic acid derivative, an acrylonitrile derivative or the like may be mixed with the polycarbonate.

The automobile 1500 may include a vehicle body 1503 and windows 1502 attached to the vehicle body 1503. The windows 1502 may each be a transparent display if it is not provided for the purpose of checking the front side and the back side of the automobile 1500. The transparent display may include the organic light emitting element according to the present exemplary embodiment. In this case, a transparent member is used as the constituent material of the electrode and the like included in the organic light emitting element.

The movable body according to the present exemplary embodiment may be a ship, an airplane, a drone or the like. The movable body may include a body and a lighting fixture provided on the body. The lighting fixture may emit light for informing the position of the body. The lighting fixture includes the organic light emitting element according to the present exemplary embodiment.

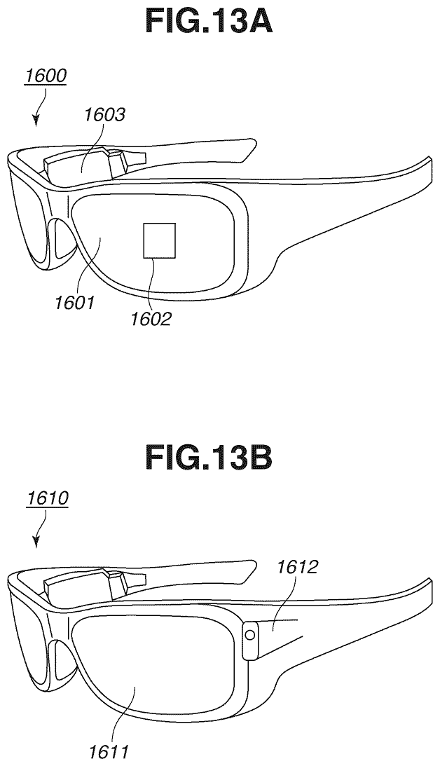

FIGS. 13A and 13B are schematic diagrams each illustrating a glasses-type display apparatus which is an example of a wearable device to which the light emitting apparatus according to an exemplary embodiment of the present invention is applied. The display apparatus can be applied to a system that can be worn on a user's body as a wearable device, such as smart glasses, a head-mounted display (HMD), or a smart contact lens, for example. An image capturing display apparatus to be used in such an application example may include an imaging apparatus that can photoelectrically convert visible light, and a display apparatus that can emit visible light.

FIG. 13A illustrate eyeglasses 1600 (smart glasses) according to an application example. An imaging apparatus 1602, such as a complementary metal-oxide semiconductor (CMOS) sensor or a single photon avalanche diode (SPAD), is provided on the front surface of each lens 1601 of the eyeglasses 1600. The display apparatus according to each of the above-described exemplary embodiments is provided on the back surface of each lens 1601.

The eyeglasses 1600 further include a control apparatus 1603. The control apparatus 1603 functions as a power source that supplies power to the imaging apparatus 1602 and the display apparatus according to each of the above-described exemplary embodiments. The control apparatus 1603 also controls operations of the imaging apparatus 1602 and the display apparatus. In the lens 1601, an optical system for condensing light on the imaging apparatus 1602 is formed.

FIG. 13B illustrates eyeglasses 1610 (smart glasses) according to an application example. The eyeglasses 1610 include a control apparatus 1612, and the control apparatus 1612 is provided with an imaging apparatus equivalent to the imaging apparatus 1602, and the display apparatus. In a lens 1611, an optical system for projecting light emitted from the imaging apparatus and the display apparatus in the control apparatus 1612 is formed, and an image is projected onto the lens 1611. The control apparatus 1612 functions as a power source that supplies power to the imaging apparatus and the display apparatus, and controls operations of the imaging apparatus and the display apparatus. The control apparatus 1612 may include a line of sight detection unit that detects the line of sight of a wearer. Infrared light may be used for the detection of a line of sight. The line of sight detection unit emits infrared light onto an eyeball of a user looking at a displayed image. An imaging unit including a light receiving element detects reflected light of the emitted infrared light that has been reflected from the eyeball, and a captured image of the eyeball is thereby obtained. By including a reduction unit for reducing light from the line of sight detection unit to a display unit in a planar view, deterioration in image quality is reduced.

From a captured image of an eyeball that has been obtained by image capturing using infrared light, the visual line of sight of the user with respect to a displayed image is detected. An arbitrary known method can be applied to the detection of the line of sight using a captured image of an eyeball. As an example, a line of sight detection method that is based on a Purkinje image obtained by the reflection of irradiation light on a cornea can be used.

More specifically, line of sight detection processing that is based on the pupil center corneal reflection method is performed. The line of sight of a user is detected by calculating a line of sight vector representing the direction (rotational angle) of an eyeball, based on an image of a pupil and a Purkinje image that are included in a captured image of the eyeball, using the pupil center corneal reflection.

The display apparatus according to an exemplary embodiment of the present invention may include an imaging apparatus including a light receiving element, and may control a displayed image on the display apparatus based on information about the line of sight of the user from the imaging apparatus.

Specifically, in the display apparatus, a first field of view region that the user gazes, and a second field of view region other than the first field of view region are determined based on the line of sight information. The first field of view region and the second field of view region may be determined by a control apparatus of the display apparatus, or the first field of view region and the second field of view region determined by an external control apparatus may be received. In a display region of the display apparatus, a display resolution in the first field of view region may be controlled to be higher than a display resolution in the second field of view region. In other words, the resolution in the second field of view region may be set to be lower than the resolution in the first field of view region.

The display region includes a first display region and a second display region different from the first display region. Based on the line of sight information, a region with high priority is determined from the first display region and the second display region. The first display region and the second display region may be determined by the control apparatus of the display apparatus, or the first display region and the second display region determined by an external control apparatus may be received. A resolution of a region with high priority may be controlled to be higher than a resolution of a region other than the region with high priority. In other words, a resolution of a region with relatively low priority may be set to a low resolution.

Artificial intelligence (AI) may be used to determine the first field of view region and a region with high priority. The AI may be a model configured to estimate an angle of a line of sight and a distance to a target existing at the end of the line of sight from an image of an eyeball using training data including an image of the eyeball, and a direction in which the eyeball in the image actually gazes. An AI program may be included in the display apparatus, may be included in the imaging apparatus, or may be included in an external apparatus. In a case where an external apparatus includes the AI program, the AI program is transmitted to the display apparatus via communication.

In a case where display control is performed based on visual recognition, the present invention can be suitably applied to smart glasses further including an imaging apparatus that captures an external image. The smart glasses can display external information obtained by image capturing in real time.

As described above, by using an apparatus that uses the organic light emitting element according to the present exemplary embodiment, it becomes possible to provide stable display for a long time with good image quality.

The present invention is not limited to the above-described exemplary embodiments, and various changes and modifications can be made without departing from the spirit and the scope of the present invention. Accordingly, the following claims are appended to publicize the scope of the present invention.

According to an exemplary embodiment of the present invention, it is possible to provide a light emitting apparatus in which, in a case where a lens is used, reduction of a color shift attributed to a viewing angle is adjusted for each color.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting apparatus comprising:
a substrate including a principal surface;
a first light emitting element, a second light emitting element, a third light emitting element, and a fourth light emitting element that are arranged on the principal surface;
a first lens that light emitted by the first light emitting element enters;
a second lens that light emitted by the second light emitting element enters;
a third lens that light emitted by the third light emitting element enters;
a fourth lens that light emitted by the fourth light emitting element enters;
a first insulating layer defining a light emitting region of the first light emitting element;
a second insulating layer defining a light emitting region of the second light emitting element;
a third insulating layer defining a light emitting region of the third light emitting element; and
a fourth insulating layer defining a light emitting region of the fourth light emitting element,
wherein the first light emitting element and the second light emitting element emit first light that is fluorescent light, and the third light emitting element and the fourth light emitting element emit second light in a wavelength different from that of the first light and is phosphorescent light,
wherein, in a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface,
wherein a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface,
wherein a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface,
wherein a size of the light emitting region of the second light emitting element is equal to or smaller than a size of the light emitting region of the first light emitting element,
wherein a size of the light emitting region of the fourth light emitting element is smaller than a size of the light emitting region of the third light emitting element, and
wherein a difference between the size of the light emitting region of the second light emitting element and the size of the light emitting region of the first light emitting element is equal to or smaller than a difference between the size of the light emitting region of the fourth light emitting element and the size of the light emitting region of the third light emitting element.

2. The light emitting apparatus according to claim 1, wherein the light emitting region of the fourth light emitting element is smaller than the light emitting region of the second light emitting element.

3. The light emitting apparatus according to claim 1, wherein the size of the light emitting region of the third light emitting element is smaller than the size of the light emitting region of the first light emitting element.

4. The light emitting apparatus according to claim 1, wherein the size of the light emitting region of the second light emitting element and the size of the light emitting region of the first light emitting element are same.

5. The light emitting apparatus according to claim 1, wherein the wavelength of the first light is shorter than the wavelength of the second light.

6. The light emitting apparatus according to claim 1, wherein the first light is blue light, and the second light is red or green light.

7. The light emitting apparatus according to claim 1, wherein the distance between the midpoint of the light emitting region of the second light emitting element and the vertex of the second lens is equal to the distance between the midpoint of the light emitting region of the fourth light emitting element and the vertex of the fourth lens.

8. The light emitting apparatus according to claim 1, wherein the difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to the difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface.

9. The light emitting apparatus according to claim 1, further comprising:
a fifth light emitting element arranged between the first light emitting element and the second light emitting element and adjacent to the second light emitting element; and
a fifth lens that light emitted by the fifth light emitting element enters,
wherein, in the cross section vertical to the principal surface, a distance between a midpoint of a light emitting region of the fifth light emitting element and a vertex of the fifth lens in the direction parallel to the principal surface is equal to the distance between the midpoint of the light emitting region of the second light emitting element and the vertex of the second lens in the direction parallel to the principal surface.

10. The light emitting apparatus according to claim 9, wherein a difference between a size of the light emitting region of the fifth light emitting element and the size of the light emitting region of the second light emitting element is smaller than a difference between the size of the light emitting region of the second light emitting element and the size of the light emitting region of the first light emitting element.

11. The light emitting apparatus according to claim 9, further comprising:
a sixth light emitting element adjacent to the second light emitting element; and
a sixth lens that light emitted by the sixth light emitting element enters,
wherein the second light emitting element is arranged between the first light emitting element and the sixth light emitting element, and
wherein, in the cross section vertical to the principal surface, a distance between a midpoint of a light emitting region of the sixth light emitting element and a vertex of the sixth lens in the direction parallel to the principal surface is larger than the distance between the midpoint of the light emitting region of the second light emitting element and the vertex of the second lens in the direction parallel to the principal surface.

12. The light emitting apparatus according to claim 11, wherein the light emitting region of the sixth light emitting element is smaller than the light emitting region of the second light emitting element.

13. The light emitting apparatus according to claim 1, further comprising:
a seventh light emitting element arranged between the third light emitting element and the fourth light emitting element and adjacent to the fourth light emitting element; and
a seventh lens that light emitted by the seventh light emitting element enters,
wherein, in the cross section vertical to the principal surface, a distance between a midpoint of a light emitting region of the seventh light emitting element and a vertex of the seventh lens in the direction parallel to the principal surface is equal to the distance between the midpoint of the light emitting region of the fourth light emitting element and the vertex of the fourth lens in the direction parallel to the principal surface.

14. The light emitting apparatus according to claim 13, wherein a difference between a size of the light emitting region of the seventh light emitting element and the size of the light emitting region of the fourth light emitting element is smaller than a difference between the size of the light emitting region of the fourth light emitting element and the size of the light emitting region of the third light emitting element.

15. The light emitting apparatus according to claim 13, further comprising:
an eighth light emitting element adjacent to the fourth light emitting element; and
an eighth lens that light emitted by the eighth light emitting element enters,
wherein the fourth light emitting element is arranged between the third light emitting element and the eighth light emitting element, and
wherein, in the cross section vertical to the principal surface, a distance between a midpoint of a light emitting region of the eighth light emitting element and a vertex of the eighth lens in the direction parallel to the principal surface is larger than the distance between the midpoint of the light emitting region of the fourth light emitting element and the vertex of the fourth lens in the direction parallel to the principal surface.

16. The light emitting apparatus according to claim 15, wherein a size of the light emitting region of the eighth light emitting element is smaller than the size of the light emitting region of the fourth light emitting element.

17. The light emitting apparatus according to claim 1, further comprising:
a fifth light emitting element that arranged between the first light emitting element and the second light emitting element and adjacent to the second light emitting element; and
a fifth lens that light emitted by the fifth light emitting element enters,
wherein, in the cross section vertical to the principal surface, a distance between a midpoint of a light emitting region of the fifth light emitting element and a vertex of the fifth lens in the direction parallel to the principal surface is smaller than the distance between the midpoint of the light emitting region of the second light emitting element and the vertex of the second lens in the direction parallel to the principal surface, and
wherein, in the cross section vertical to the principal surface, the distance between the midpoint of the light emitting region of the fifth light emitting element and the vertex of the fifth lens in the direction parallel to the principal surface is larger than the distance between the midpoint of the light emitting region of the first light emitting element and the vertex of the first lens in the direction parallel to the principal surface.

18. The light emitting apparatus according to claim 17, wherein a size of the light emitting region of the fifth light emitting element is larger than the size of the light emitting region of the second light emitting element and smaller than the size of the light emitting region of the first light emitting element.

19. The light emitting apparatus according to claim 17, further comprising:
a sixth light emitting element adjacent to the second light emitting element; and
a sixth lens that light emitted by the sixth light emitting element enters,
wherein the second light emitting element is arranged between the first light emitting element and the sixth light emitting element,
wherein, in the cross section vertical to the principal surface, a distance between a midpoint of a light emitting region of the sixth light emitting element and a vertex of the sixth lens in the direction parallel to the principal surface is larger than the distance between the midpoint of the light emitting region of the second light emitting element and the vertex of the second lens in the direction parallel to the principal surface.

20. The light emitting apparatus according to claim 19, wherein a size of the light emitting region of the sixth light emitting element is smaller than the size of the light emitting region of the second light emitting element.

21. The light emitting apparatus according to claim 17, further comprising:
a seventh light emitting element arranged between the third light emitting element and the fourth light emitting element and adjacent to the fourth light emitting element; and
a seventh lens that light emitted by the seventh light emitting element enters,
wherein, in the cross section vertical to the principal surface, a distance between a midpoint of a light emitting region of the seventh light emitting element and a vertex of the seventh lens in the direction parallel to the principal surface is smaller than the distance between the midpoint of the light emitting region of the fourth light emitting element and the vertex of the fourth lens in the direction parallel to the principal surface, and
wherein, in the cross section vertical to the principal surface, the distance between the midpoint of the light emitting region of the seventh light emitting element and the vertex of the seventh lens in the direction parallel to the principal surface is larger than the distance between the midpoint of the light emitting region of the third light emitting element and the vertex of the third lens in the direction parallel to the principal surface.

22. The light emitting apparatus according to claim 21, wherein a size of the light emitting region of the seventh light emitting element is smaller than the size of the light emitting region of the third light emitting element and larger than the size of the light emitting region of the fourth light emitting element.

23. A light emitting apparatus comprising:
a substrate including a principal surface;
a first light emitting element, a second light emitting element, a third light emitting element, and a fourth light emitting element that are arranged on the principal surface;
a first lens that light emitted by the first light emitting element enters;
a second lens that light emitted by the second light emitting element enters;
a third lens that light emitted by the third light emitting element enters; and
a fourth lens that light emitted by the fourth light emitting element enters;
wherein the first light emitting element and the second light emitting element emit first light, and the third light emitting element and the fourth light emitting element emit second light in a wavelength different from that of the first light,
wherein, in a cross section vertical to the principal surface, a distance between a midpoint of a light emitting region of the second light emitting element and a vertex of the second lens in a direction parallel to the principal surface is larger than a distance between a midpoint of a light emitting region of the first light emitting element and a vertex of the first lens in the direction parallel to the principal surface,
wherein a distance between a midpoint of a light emitting region of the fourth light emitting element and a vertex of the fourth lens in the direction parallel to the principal surface is larger than a distance between a midpoint of a light emitting region of the third light emitting element and a vertex of the third lens in the direction parallel to the principal surface,
wherein a difference between the distance between the midpoint of the light emitting region of the second light emitting element and the vertex of the second lens in the direction parallel to the principal surface and the distance between the midpoint of the light emitting region of the first light emitting element and the vertex of the first lens in the direction parallel to the principal surface is equal to or smaller than a difference between the distance between the midpoint of the light emitting region of the fourth light emitting element and the vertex of the fourth lens in the direction parallel to the principal surface and the distance between the midpoint of the light emitting region of the third light emitting element and the vertex of the third lens in the direction parallel to the principal surface, and
wherein lens efficiency of the first lens is smaller than lens efficiency of the second lens, lens efficiency of the third lens is smaller than lens efficiency of the fourth lens, and the lens efficiency of the fourth lens is smaller than lens efficiency of the second lens.

24. A light emitting apparatus comprising:
a substrate including a principal surface;
a first light emitting element and a second light emitting element arranged on the principal surface and configured to emit light with a first color;
a first lens that light emitted by the first light emitting element enters;
a second lens that light emitted by the second light emitting element enters;
a third light emitting element and a fourth light emitting element arranged on the principal surface and configured to emit light with a second color different from the first color;
a third lens that light emitted by the third light emitting element enters; and
a fourth lens that light emitted by the fourth light emitting element enters;
wherein, in a direction parallel to the principal surface, a distance between a midpoint of a light emitting region of the second light emitting element and a vertex of the second lens is larger than a distance between a midpoint of a light emitting region of the first light emitting element and a vertex of the first lens,
wherein, in the direction parallel to the principal surface, a distance between a midpoint of a light emitting region of the fourth light emitting element and a vertex of the fourth lens is larger than a distance between a midpoint of a light emitting region of the third light emitting element and a vertex of the third lens, and
wherein the distance between the midpoint of the light emitting region of the second light emitting element and the vertex of the second lens is equal to the distance between the midpoint of the light emitting region of the fourth light emitting element and the vertex of the fourth lens,
wherein the light emitting region of the third light emitting element is larger than the light emitting region of the first light emitting element, and
wherein the light emitting region of the fourth light emitting element is larger than the light emitting region of the second light emitting element.

25. A display apparatus comprising:
a plurality of pixels,
wherein at least one of the plurality of pixels includes the light emitting apparatus according to claim 1, and a display control unit configured to control display on the light emitting apparatus.

26. An imaging apparatus comprising:
an optical unit including a plurality of lenses;
an image sensor configured to receive light having passed through the optical unit; and
a display unit configured to display an image captured by the image sensor,
wherein the display unit includes the light emitting apparatus according to claim 1.

27. An electronic device comprising:
a display unit including the light emitting apparatus according to claim 1;
a housing on which the display unit is provided; and
a communication unit provided on the housing and configured to communicate with an external device.
